(19) United States
(12) Patent Application Publication
(10) Pub. No.: US 2025/0219586 A1
(43) Pub. Date: Jul. 3, 2025

(54) DOHERTY AMPLIFIER

(71) Applicant: Mitsubishi Electric Corporation, Tokyo (JP)

(72) Inventor: Katsuya KATO, Tokyo (JP)

(73) Assignee: Mitsubishi Electric Corporation, Tokyo (JP)

(21) Appl. No.: 18/631,724

(22) Filed: Apr. 10, 2024

(30) Foreign Application Priority Data
Dec. 27, 2023 (JP) 2023-220795

(51) Int. Cl. H03F 1/02; H01L 23/36; H01L 23/66; H03F 3/21

(52) U.S. Cl. CPC H03F 1/0288; H01L 23/36; H01L 23/66; H03F 3/211; H01L 2223/6611; H01L 2223/6655; H03F 2200/318

(57) ABSTRACT

A Doherty amplifier according to an aspect of the present disclosure includes a heat sink; a resin substrate mounted on the heat sink, and having a cavity formed to expose the heat sink, the resin substrate being formed by stacking a plurality of resin layers and a plurality of metal layers; a main amplifier mounted in the cavity; a peak amplifier mounted in the cavity; and an inductor, wherein the resin substrate has a partition wall part that separates at least a portion of the main amplifier from at least a portion of the peak amplifier, the plurality of metal layers of the partition wall part are electrically connected to the heat sink, and the inductor is mounted on the partition wall part, and electrically connected to the plurality of metal layers.

### BACKGROUND

### Field

The present disclosure relates to a Doherty amplifier.

### Background

JP 2015-12609 A discloses a semiconductor package having a wire bond wall for reducing coupling. This package includes a substrate, and a first circuit on the substrate. The first circuit includes a first electrical device, a second electrical device, and a first wire bond array that interconnects the first electrical device and the second electrical device. The package includes a second circuit adjacent to the first circuit on the substrate, and the second circuit includes a second wire bond array that interconnects a third electrical device and a fourth electrical device. The package includes, between the first circuit and the second circuit, a wire bond wall including a plurality of wire bonds on the substrate. The wire bond wall is configured to reduce electromagnetic coupling between the first circuit and the second circuit during operation of at least one of the first circuit and the second circuit.

In wireless communication, digital modulation signals having a large peak-to-average power ratio (PAPR) are used to achieve high-speed, large-capacity communication. The Doherty amplifier is widely used as a circuit for amplifying the signals with low distortion and high efficiency, even for such modulated signals having a large PAPR. In the Doherty amplifier, a main amplifier biased to class AB and a peak amplifier biased to class C are combined in parallel through 90-degree delay lines disposed at an input and an output. Moreover, in order to reduce size and cost, the main amplifier and the peak amplifier are often disposed adjacent to each other. When the circuits are adjacent to each other, there is a risk of deterioration of isolation between a main amplifier path and a peak amplifier path. Consequently, there is a possibility of occurrence of problems such as deterioration of characteristics and oscillation.

For such problems, JP 2015-12609 A discloses providing an electrical shield between the paths. With this structure, it is possible to improve the isolation between the paths. However, in JP 2015-12609 A, a dedicated member and a special assembly step are required to form the shield. Therefore, there is a risk of an increase in the manufacturing cost.

### SUMMARY

The present disclosure has been made to solve the above-mentioned problems, and aims to obtain a Doherty amplifier capable of improving the isolation between the main amplifier and the peak amplifier at low cost.

The features and advantages of the present disclosure may be summarized as follows.

According to an aspect of the present disclosure, a Doherty amplifier includes a heat sink; a resin substrate mounted on the heat sink, and having a cavity formed to expose the heat sink, the resin substrate being formed by stacking a plurality of resin layers and a plurality of metal layers; a main amplifier mounted in the cavity; a peak amplifier mounted in the cavity; and an inductor, wherein the resin substrate has a partition wall part that separates at least a portion of the main amplifier from at least a portion of the peak amplifier, the plurality of metal layers of the partition wall part are electrically connected to the heat sink, and the inductor is mounted on the partition wall part, and electrically connected to the plurality of metal layers.

Other and further objects, features and advantages of the disclosure will appear more fully from the following description.

### BRIEF DESCRIPTION OF DRAWINGS

FIG. 1 is a view explaining a circuit configuration of a Doherty amplifier according to a first embodiment.

FIG. 2 is a perspective view of the Doherty amplifier according to the first embodiment.

FIG. 3 is a cross-sectional view of a shield according the first embodiment.

FIG. 4 is a view explaining the connection between each inductor and the heat sink according to the first embodiment.

FIG. 5 is a view explaining a circuit configuration of a Doherty amplifier according to a comparative example.

FIG. 6 is a perspective view of the Doherty amplifier according to the comparative example.

FIG. 7 is a plan view of the Doherty amplifier according to the comparative example.

FIG. 8 is a view explaining a circuit configuration of a Doherty amplifier according to a second embodiment.

FIG. 9 is a perspective view of the Doherty amplifier according to the second embodiment.

FIG. 10 is a perspective view of a Doherty amplifier according to a third embodiment.

FIG. 11 is a view explaining a circuit configuration of an isolation improvement circuit according to a fourth embodiment.

FIG. 12 and FIG. 13 are views explaining the effect of the isolation improvement circuit according to the fourth embodiment.

FIG. 14 is a perspective view of the Doherty amplifier according to the fourth embodiment.

### DESCRIPTION OF EMBODIMENTS

A Doherty amplifier according to each embodiment will be described with reference to the accompanying drawings. Components identical or corresponding to each other are indicated by the same reference characters, and repeated description of them is avoided in some cases.

### First Embodiment

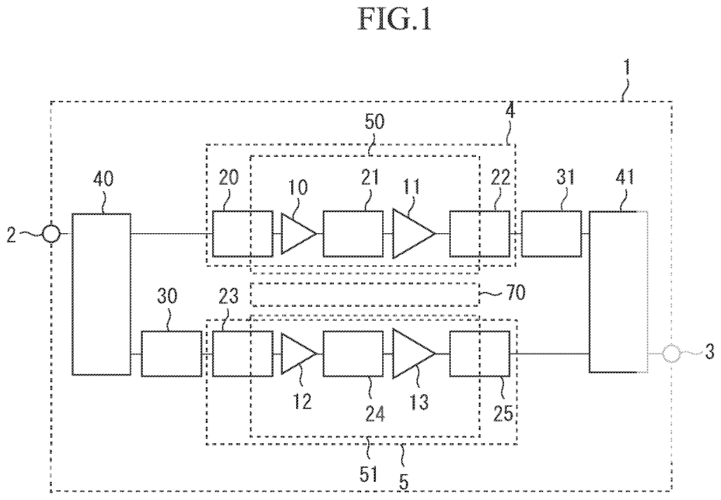

FIG. 1 is a view explaining a circuit configuration of a Doherty amplifier 1 according to a first embodiment. The Doherty amplifier 1 is used, for example, as a power amplifier for wireless communication. The Doherty amplifier 1 includes a main amplifier 4, a peak amplifier 5, 90-degree delay circuits 30, 31, a dividing circuit 40, a combining circuit 41, an input terminal 2, and an output terminal 3. The input terminal 2 is connected to the dividing circuit 40. The dividing circuit 40 has outputs connected to the main amplifier 4 and the 90-degree delay circuit 30. An output of the 90-degree delay circuit 30 is connected to an input of the peak amplifier 5. The 90-degree delay circuit 31 is connected to an output of the main amplifier 4. An output of the 90-degree delay circuit 31 and an output of the peak amplifier 5 are connected to the combining circuit 41. An output of the combining circuit 41 is connected to the output terminal 3.

In the main amplifier 4, an input matching circuit 20, a first stage transistor 10, an inter-stage matching circuit 21, a final stage transistor 11, and an output matching circuit 22 are connected in this order. The first stage transistor 10 corresponds to a first main amplifier that is connected to the input terminal 2 side of the Doherty amplifier 1, and the final stage transistor 11 corresponds to a second main amplifier that is connected to the output terminal 3 side of the Doherty amplifier 1. The inter-stage matching circuit 21 connects the first main amplifier to the second main amplifier.

In the peak amplifier 5, an input matching circuit 23, a first stage transistor 12, an inter-stage matching circuit 24, a final stage transistor 13, and an output matching circuit 25 are connected in this order. The first stage transistor 12 corresponds to a first peak amplifier that is connected to the input terminal 2 side of the Doherty amplifier 1, and the final stage transistor 13 corresponds to a second peak amplifier that is connected to the output terminal 3 side of the Doherty amplifier 1. The inter-stage matching circuit 24 connects the first peak amplifier to the second peak amplifier.

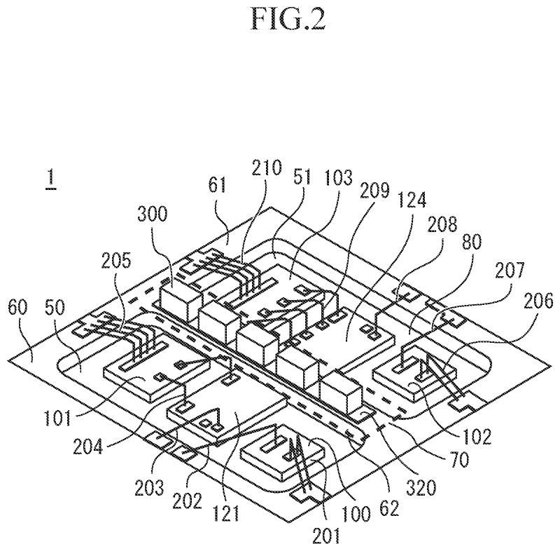

FIG. 2 is a perspective view of the Doherty amplifier 1 according to the first embodiment. In the main amplifier 4, the first stage transistor 10 is configured as a first stage transistor chip 100, and the final stage transistor 11 is configured as a final stage transistor chip 101. Moreover, part of the output matching circuit 22 is also configured as the final stage transistor chip 101. The remaining part of the output matching circuit 22 is formed on a resin substrate 60. An inter-stage matching circuit chip 121 has a circuit formed on the chip, and constitutes part of the inter-stage matching circuit 21 of the main amplifier 4. Thus, the main amplifier 4 is constituted by a plurality of chips. The transistor chip and a surface layer metal of the resin substrate 60, the transistor chip and the inter-stage matching circuit chip 121, and the inter-stage matching circuit chip 121 and the surface layer metal of the resin substrate 60 are connected by wires 201 to 205, which are each bonding wires.

In the peak amplifier 5, the first stage transistor 12 is configured as a first stage transistor chip 102, and the final stage transistor 13 is configured as a final stage transistor chip 103. Moreover, part of the output matching circuit 25 is also configured as the final stage transistor chip 103. The remaining part of the output matching circuit 25 is formed on the resin substrate 60. An inter-stage matching circuit chip 124 has a circuit formed on the chip, and constitutes part of the inter-stage matching circuit 24 of the peak amplifier 5. Thus, the peak amplifier 5 is constituted by a plurality of chips. The transistor chip and a surface layer metal of the resin substrate 60, the transistor chip and the inter-stage matching circuit chip 124, and the inter-stage matching circuit chip 124 and the surface layer metal of the resin substrate 60 are connected by wires 206 to 210, which are each bonding wires.

The wires 202, 203, 207, 208 are connected to electrode pads on the resin substrate 60. Thus, part of the inter-stage matching circuits 21, 24 can be formed on the resin substrate 60. Further, the above-mentioned configuration enables supply of a drain voltage of the first stage transistors 10, 12, and a gate voltage of the final stage transistors 11, 13. Note that, in FIGS. 1 and 2, detailed layouts of a drain bias circuit, a gate bias circuit, and semiconductor chips are omitted.

The Doherty amplifier 1 is integrated into one package. The package includes a heat sink 80, and the resin substrate 60 mounted on the heat sink 80. The multi-layer resin substrate 60 is formed by stacking a plurality of resin layers and a plurality of metal layers. A portion of the resin substrate 60 is hollowed out, and a cavity is formed to expose the heat sink 80. The main amplifier 4 and the peak amplifier 5 are mounted in the cavity.

It is possible to realize low thermal resistance by directly die-bonding the first stage transistor chips 100, 102, the final stage transistor chips 101, 103, and the inter-stage matching circuit chips 121, 124 to the heat sink 80 within the cavity.

Moreover, the input matching circuits 20, 23, the output matching circuits 22, 25, the dividing circuit 40, and the combining circuit 41 are formed on the resin substrate 60. These circuits are formed by combining lines, chip inductors, chip capacitors, chip resistors, etc. on the resin substrate 60.

The resin substrate 60 has an annular portion 61 that forms the cavity, and a partition wall part 62 that extends between the second main amplifier and the second peak amplifier from the annular portion 61. In other words, the partition wall part 62 extends between the final stage transistor chips 101 and 103. In the present embodiment, the cavity is divided into a first cavity 50 and a second cavity 51 by the partition wall part 62. The main amplifier 4 is mounted in the first cavity 50, and the peak amplifier 5 is mounted in the second cavity 51.

Note that the state in which the main amplifier 4 is mounted in the cavity means a state in which at least part of the main amplifier 4 is mounted in the cavity, and the entire main amplifier 4 is not necessarily mounted in the cavity. Similarly, the state in which the peak amplifier 5 is mounted in the cavity means a state in which at least part of the peak amplifier 5 is mounted in the cavity, and the entire peak amplifier 5 is not necessarily mounted in the cavity. Further, a plurality of inductors 300 are mounted on the partition wall part 62. The plurality of inductors 300 are, for example, chip inductors.

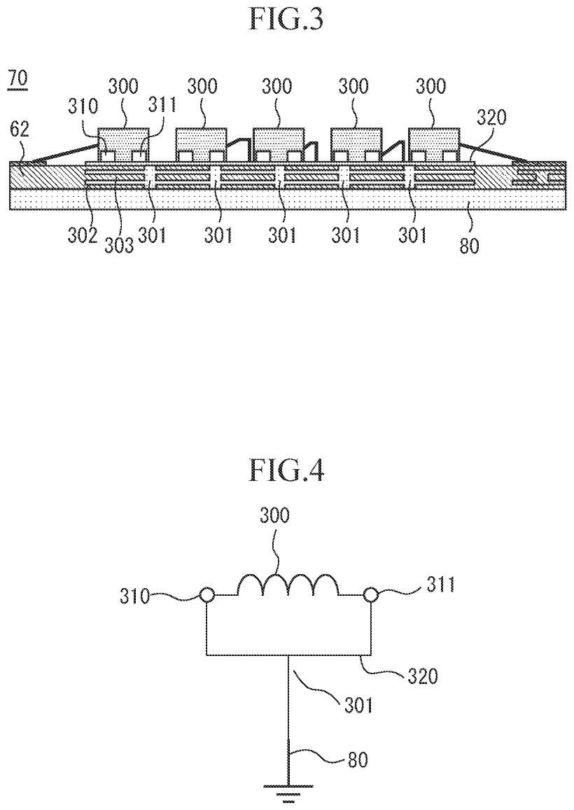

FIG. 3 is a cross-sectional view of a shield 70 according the first embodiment. The shield 70 is disposed between the first cavity 50 and the second cavity 51. The shield 70 has the partition wall part 62 of the resin substrate 60, and the inductors 300. In the partition wall part 62 that is a portion of the resin substrate 60, a plurality of resin layers 303 and a plurality of metal layers 302 are stacked. The surface layer metal 320 and the plurality of metal layers 302 of the partition wall part 62, and the heat sink 80 are electrically connected through the plurality of VIA holes 301 formed in the resin substrate 60.

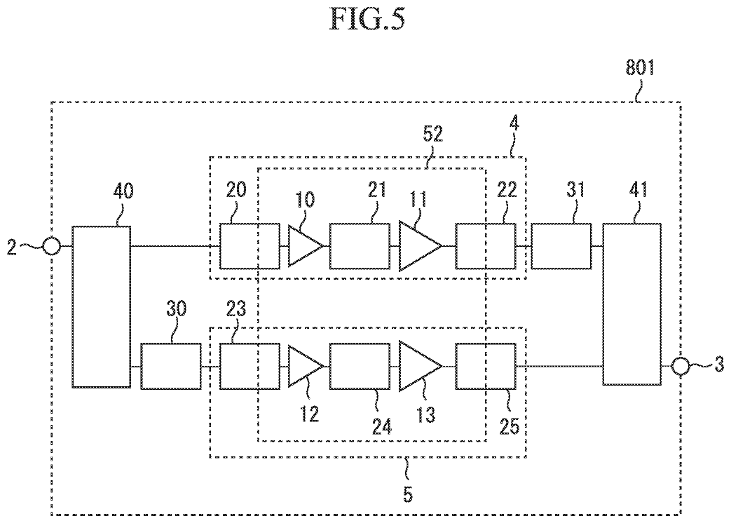

Further, the plurality of inductors 300 are disposed on the surface layer metal 320. The inductors 300 are electrically connected to the plurality of metal layers 302. FIG. 4 is a view explaining the connection between each inductor 300 and the heat sink 80 according to the first embodiment. Electrodes 310, 311 at both ends of the inductor 300 are each connected to the heat sink 80 through the surface layer metal 320 and the VIA hole 301. The heat sink 80 is a GND. From the above, the inductor 300, the VIA hole 301, and the heat sink 80 have the same potential.

The VIA holes 301 and the inductors 300 are preferably arranged at a high density within a range of design rules of the resin substrate 60. The resin substrate 60 is, for example, made of a material such as FR4, and the substrate thickness is between 200 and 400 μm. The heat sink 80 is made of a material with low thermal resistance, such as copper. The first stage transistor chips 100, 102 and the final stage transistor chips 101, 103 are, for example, GaN-HEMT formed on a SiC substrate. For the inter-stage matching circuit chips 121, 124, for example, inexpensive semiconductor substrates such as GaAs or Si substrates are used. Without limiting to this, for example, a circuit may be formed on a dielectric thin plate to form the inter-stage matching circuit chips 121, 124. Each inductor 300 is, for example, a general-purpose chip inductor of 0603 size or 0402 size. The inductor 300 preferably has a high internal metal density and a large inductance value, and allowable current values are not limited.

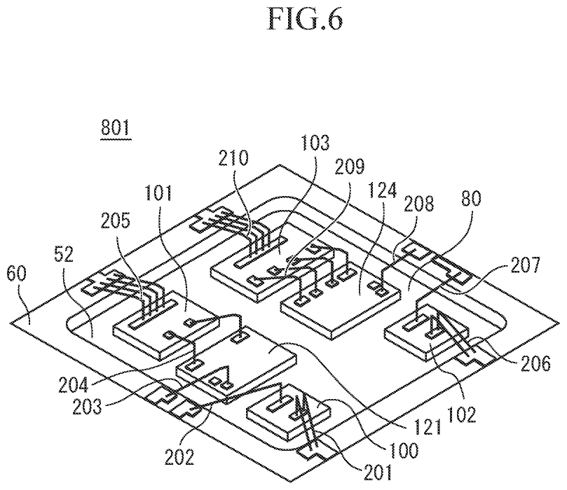

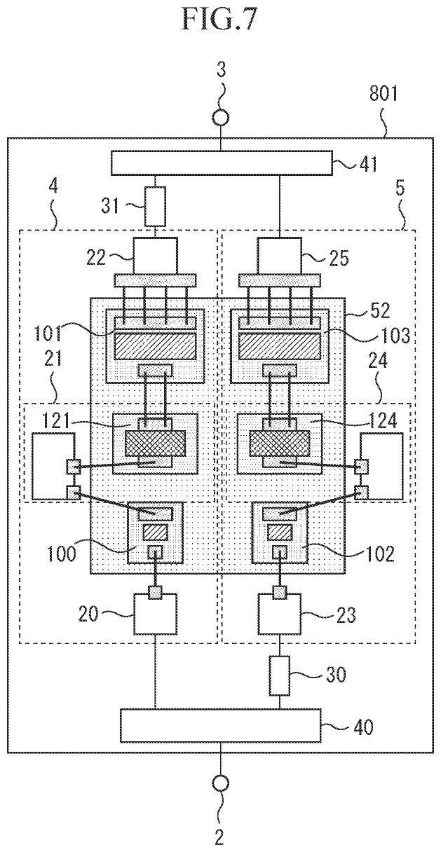

FIG. 5 is a view explaining a circuit configuration of a Doherty amplifier 801 according to a comparative example. FIG. 6 is a perspective view of the Doherty amplifier 801 according to the comparative example. FIG. 7 is a plan view of the Doherty amplifier 801 according to the comparative example. The comparative example is different from the present embodiment in that the partition wall part 62 and the inductors 300 are not provided. In other words, the main amplifier 4 and the peak amplifier 5 are mounted in a common cavity 52. The rest of the configuration is the same as the configuration of the present embodiment.

Problems of the Doherty amplifier 801 according to such a comparative example will be described. The final stage transistor chips 101, 103, the inter-stage matching circuit chips 121, 124, and the first stage transistor chips 100, 102 are disposed adjacent to each other for miniaturization. Therefore, the wires 204, 209 are easily coupled electromagnetically. Consequently, the isolation between the main amplifier 4 and the peak amplifier 5 may deteriorate, and there are risks of occurrence of problems such as deterioration of RF characteristics, and oscillation.

On the other hand, in the present embodiment, the cavity is divided into two cavities, and the shield 70 constituted by the partition wall part 62 and the inductors 300 is disposed between these cavities. The VIA holes 301 are electrically connected to the heat sink 80 as the GND of the circuit, and the VIA holes 301 and the inductors 300 are also electrically connected. The isolation between the main amplifier 4 and the peak amplifier 5 can be improved by such a shield 70 having the same potential as the GND. Therefore, it is possible to reduce the deterioration of RF characteristics, occurrence of oscillation, and a decrease in stability.

Moreover, it is possible to increase the height of the shield 70 by adding the inductors 300. When a current flows through the bonding wire, magnetic flux is generated around the current. By forming the shield 70 to block the magnetic flux, electromagnetic field coupling can be effectively reduced. A top surface of each of the inductors 300 may be arranged at a higher position than the wires that connect the plurality of chips constituting the main amplifier 4 or the peak amplifier 5.

Further, metal windings are integrated at a high density inside a chip inductor. If the chip inductor filled with metal at a high density is used as the inductor 300, the isolation can be further improved.

Furthermore, it is possible to constitute the shield 70 by the VIA holes 301, which are formed when the resin substrate 60 is produced, and the chip inductors which are general-purpose products. In other words, no dedicated part is required, and no special assembly step is required. Consequently, the isolation between the main amplifier 4 and the peak amplifier 5 can be improved at low cost. As described above, in the present embodiment, the chip inductors, chip capacitors, and chip resistors are used for the matching circuits. The inductors 300 serving as the shield 70 may be mounted in a step for mounting these parts. Thus, it is possible to mount the chip inductors on the shield 70 without adding a manufacturing step.

In the present embodiment, an example in which each of the main amplifier 4 and the peak amplifier 5 is a two-stage amplifier is described. Even when the main amplifier 4 and the peak amplifier 5 are not limited to this and are one-stage, or three or more-stage amplifiers, similar effects can be obtained.

These modifications can be appropriately applied to Doherty amplifiers according to embodiments below. Meanwhile, for the Doherty amplifiers according to the embodiments below, dissimilarities with the first embodiment will mainly be explained as they have many similarities with the first embodiment.

### Second Embodiment

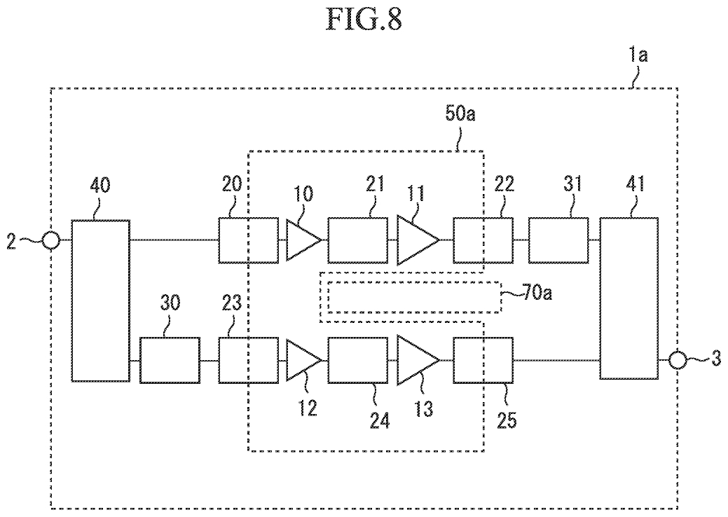

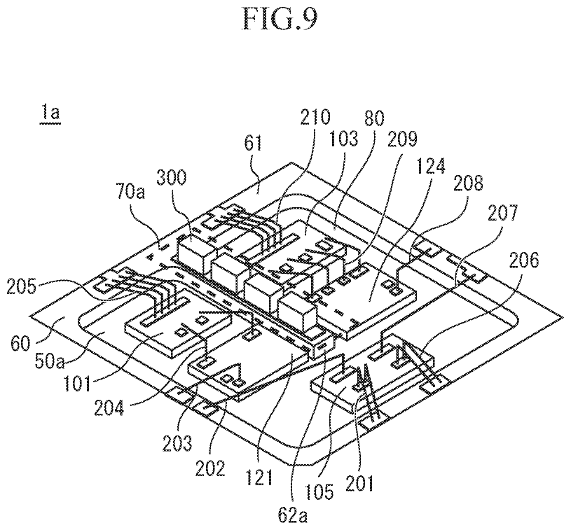

FIG. 8 is a view explaining a circuit configuration of a Doherty amplifier 1a according to a second embodiment. FIG. 9 is a perspective view of the Doherty amplifier 1a according to the second embodiment. The structure of a shield 70a in the present embodiment is different from the structure in the first embodiment. The shield 70a does not divide the cavity into two, and is disposed between the final stage transistor chips 101, 103 and between the inter-stage matching circuit chips 121, 124. In other words, in the present embodiment, one cavity 50a is formed in the resin substrate 60. Thus, a partition wall part 62a may separate at least a portion of the main amplifier 4 from at least a portion of the peak amplifier 5.

Moreover, the transistor chips 100, 102 are commonized and configured as one transistor chip 105. In other words, the first stage transistors 10, 12 are mounted on one transistor chip 105. The transistor chip 105 has two gate pads, and two drain pads. The rest of the configuration is the same as the configuration in the first embodiment.

In the present embodiment, the isolation between the main amplifier 4 and the peak amplifier 5 can also be improved by the shield 70a. Moreover, since the first stage transistor chips can be integrated into one, the Doherty amplifier 1a can be manufactured at lower cost. Here, the interference between wires is likely to affect the deterioration of the isolation. Further, the lower the impedance of the circuit to which the wires are connected, the larger the effect. A gate of the transistor has particularly low impedance. Furthermore, the larger the size of the transistor, the lower the impedance of the gate. Therefore, the interference between the wires 204, 209 connected to the gates of the final stage transistor chips 101, 103 is considered particularly likely to affect the isolation. In the present embodiment, the isolation can be improved efficiently by providing the shield 70a between the wires 204, 209.

### Third Embodiment

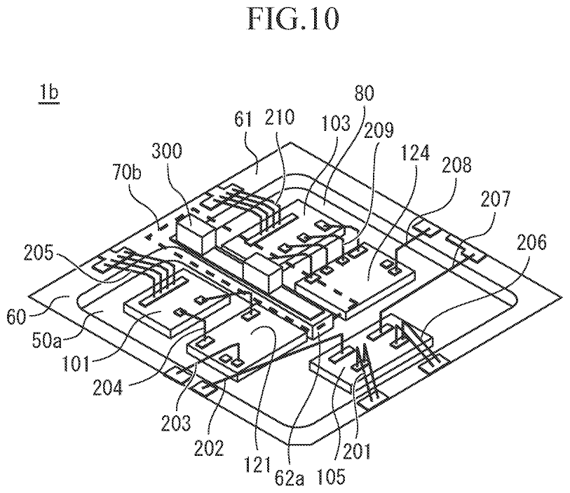

FIG. 10 is a perspective view of a Doherty amplifier 1b according to a third embodiment. In the present embodiment, the arrangement of the inductors 300 is different from the arrangement in the second embodiment. The rest of the configuration is the same as the configuration in the second embodiment. The plurality of inductors 300 are mounted on the top surface of the partition wall part 62a locally at positions adjacent to the wires 204, 205, 209, 210 connected to the final stage transistor chip 101 or the final stage transistor chip 103.

More specifically, one of the inductors 300 separates the wire 204, which connects the inter-stage matching circuit chip 121 to the final stage transistor chip 101, from the wire 209 which connects the inter-stage matching circuit chip 124 to the final stage transistor chip 103. Moreover, one of the inductors 300 separates the wire 205, which is connected to the output side of the final stage transistor chip 101, from the wire 210 which is connected to the output side of the final stage transistor chip 103.

As described above, the deterioration of the isolation between the main amplifier 4 and the peak amplifier 5 is dominantly caused by the interference between the bonding wires. Therefore, even when the inductors 300 are disposed limitedly only between the wires, a sufficient effect of improving the isolation is obtained. Further, since the number of the inductors 300 to be mounted can be reduced, it is possible to further reduce the cost.

Note that the arrangement of the inductors 300 as in the present embodiment may be employed in the first embodiment. For example, the inductor 300 may be mounted only between the wires 204, 209.

### Fourth Embodiment

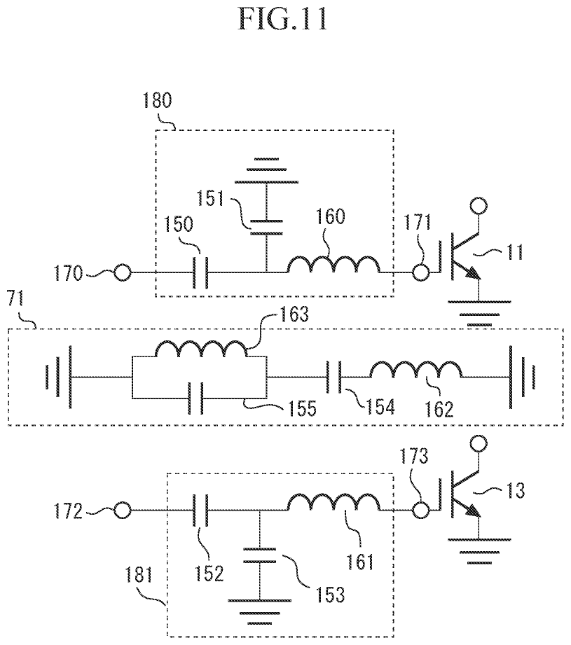

FIG. 11 is a view explaining a circuit configuration of an isolation improvement circuit 71 according to a fourth embodiment. The present embodiment is different from the first embodiment in that the isolation improvement circuit 71 is provided instead of the shield 70. The rest of the configuration is the same as the configuration in the first embodiment.

A circuit 180 represents a portion of the inter-stage matching circuit 21 of the main amplifier 4, and a circuit 181 represents a portion of the inter-stage matching circuit 24 of the peak amplifier 5. An inductor 160 corresponds to the wire 204, and an inductor 161 corresponds to the wire 209. Capacitors 151, 153 are the capacitors of the inter-stage matching circuits 21, 24, and capacitors 150, 152 are DC cut capacitors of the inter-stage matching circuits 21, 24. An input and an output of the circuit 180 are defined as nodes 170, 171, respectively. An input and an output of the circuit 181 are defined as nodes 172, 173, respectively.

The isolation improvement circuit 71 is disposed between the main amplifier 4 and the peak amplifier 5. The isolation improvement circuit 71 has a parallel circuit in which an inductor 163 and a capacitor 155 are connected in parallel. Moreover, the isolation improvement circuit 71 has a series circuit in which an inductor 162 and a capacitor 154 are connected in series. One end of the parallel circuit is electrically connected to the GND, that is, the heat sink 80. Another end of the parallel circuit is electrically connected to one end of the series circuit. Another end of the series circuit is electrically connected to the heat sink 80.

The deterioration of the isolation between the paths of the main amplifier 4 and the peak amplifier 5 is likely to occur between the inductors 160, 161. Therefore, the inductor 162 is preferably disposed adjacent to the inductors 160, 161. A resonant frequency of the parallel circuit is set to be equal to an operating center frequency of the Doherty amplifier 1c. Moreover, the inductance and capacitance values of the inductor 162 and the capacitor 154 are set according to an isolation frequency desired to be improved between the main amplifier 4 and the peak amplifier 5.

Since the inductor 162 is adjacent to the inductors 160, 161, the inductor 162 is intercoupled to the inductors 160, 161. However, since the parallel circuit constituted by the inductor 163 and the capacitor 155 is open at the operating center frequency, even if the inductor 162 is coupled to the inductors 160, 161, the isolation improvement circuit 71 does not affect the Doherty amplifier 1c at the operating center frequency. On the other hand, the parallel circuit of the inductor 163 and the capacitor 155 is not open at frequencies other than the operating center frequency. Therefore, it is possible to form a short circuit point at a specific frequency by appropriately setting constants of the inductor 162 and the capacitor 154. Like the shield, the isolation improvement circuit 71 improves the isolation between the paths at this frequency.

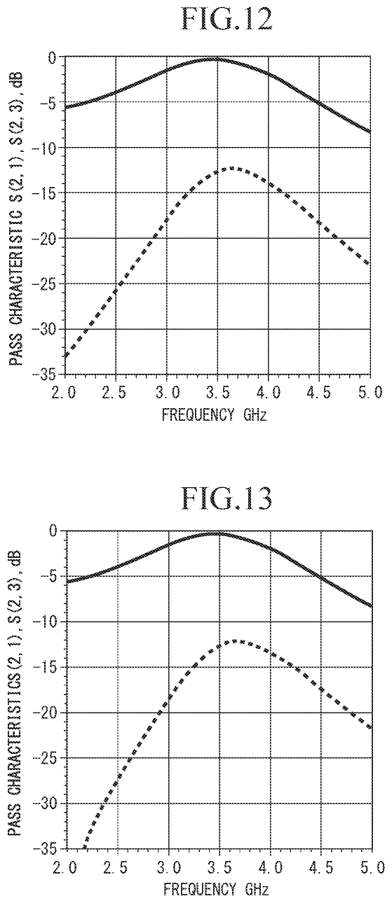

FIG. 12 and FIG. 13 are views explaining the effect of the isolation improvement circuit 71 according to the fourth embodiment. The solid line in FIG. 12 shows the calculation result of a pass characteristic from the node 170 to the node 171 when there is no isolation improvement circuit 71. The broken line in FIG. 12 shows the calculation result of a pass characteristic from the node 172 to the node 171, which indicates the isolation between the paths when there is no isolation improvement circuit 71. Each of the inductors 160, 161 is 0.44 nH, each of the capacitors 151, 153 is 4.5 pF, and a coupling coefficient between the inductors 160, 161 is 0.1. Moreover, the operating frequency of the circuit is 3.5 GHz.

The solid line in FIG. 13 shows the calculation result of the pass characteristic from the node 170 to the node 171 when the isolation improvement circuit 71 is applied. The broken line in FIG. 13 shows the calculation result of the pass characteristic from the node 172 to the node 171 when the isolation improvement circuit 71 is applied. The inductor 162 constituting the isolation improvement circuit 71 is 0.35 nH, the inductor 163 is 0.69 nH, the capacitor 154 is 5 pF, and the capacitor 155 is 3.0 pF. A coupling coefficient between the inductor 160 and the inductor 162, and a coupling coefficient between the inductor 161 and the inductor 162 are each 0.2.

A comparison of the calculation results in FIGS. 12, 13 indicates that the pass characteristic of the path of the main amplifier 4 does not change at the center frequency of 3.5 GHz. In other words, it can be understood that the isolation improvement circuit 71 does not affect the characteristics of an operating frequency band of the Doherty amplifier 1c. Moreover, it can be understood that the isolation between the paths on the low frequency side is improved by providing the isolation improvement circuit 71.

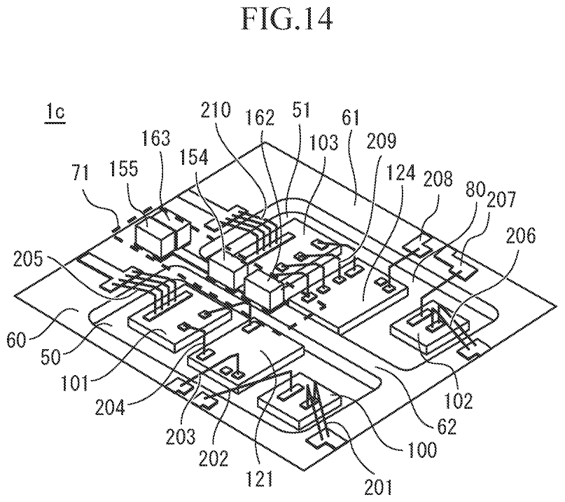

From the above, in the present embodiment, it is possible to selectively improve the isolation at a specific frequency, without affecting the operation at the operating center frequency. The present embodiment is particularly useful when the operation of the Doherty amplifier is entirely unstable due to deterioration of the isolation between the paths at a specific frequency. FIG. 14 is a perspective view of the Doherty amplifier 1c according to the fourth embodiment. The inductor 162 and the capacitor 154 constituting the series circuit are mounted on the partition wall part 62. Moreover, the inductor 163 and the capacitor 155 constituting the parallel circuit are mounted on the annular portion 61. In the present embodiment, the series circuit and the parallel circuit are also electrically connected to the heat sink 80 through the metal layer of the resin substrate 60 and the VIA holes 301.

The inductor 162 separates the wire 204, which connects the inter-stage matching circuit chip 121 to the final stage transistor chip 101, from the wire 209 which connects the inter-stage matching circuit chip 124 to the final stage transistor chip 103.

In the isolation improvement circuit 71, the inductors 162, 163 are, for example, chip inductors, and the capacitors 154, 155 are, for example, chip capacitors. Therefore, the isolation improvement circuit 71 can be configured by changing wiring connections of the resin substrate 60 from the first embodiment. Since the isolation improvement circuit 71 can be configured using the chip inductors and the chip capacitors, no dedicated part is required, and no special assembly step is required. Consequently, the isolation between the main amplifier 4 and the peak amplifier 5 can be improved at low cost.

As a modified example of the present embodiment, the inductor 163 constituting the parallel circuit may separate the wires 204, 209. The inductor 162 or the inductor 163 may separate the wire 205, which is connected to the output side of the final stage transistor chip 101, from the wire 210 which is connected to the output side of the final stage transistor chip 103. Moreover, the isolation improvement circuit 71 of the present embodiment may be applied to the partition wall part 62a of the second embodiment.

Meanwhile, technical features explained in each embodiment may be appropriately combined to use.

Hereinafter, various aspects of the present disclosure will be collectively described as appendixes.

### (Appendix 1)

A Doherty amplifier comprising:
a heat sink;
a resin substrate mounted on the heat sink, and having a cavity formed to expose the heat sink, the resin substrate being formed by stacking a plurality of resin layers and a plurality of metal layers;
a main amplifier mounted in the cavity;
a peak amplifier mounted in the cavity; and
an inductor, wherein
the resin substrate has a partition wall part that separates at least a portion of the main amplifier from at least a portion of the peak amplifier,
the plurality of metal layers of the partition wall part are electrically connected to the heat sink, and
the inductor is mounted on the partition wall part, and electrically connected to the plurality of metal layers.

### (Appendix 2)

The Doherty amplifier according to appendix 1, wherein the inductor is a chip inductor.

### (Appendix 3)

The Doherty amplifier according to appendix 1 or 2, wherein the plurality of metal layers and the heat sink are electrically connected through a VIA hole formed in the resin substrate.

### (Appendix 4)

The Doherty amplifier according to any one of appendixes 1 to 3, wherein
the main amplifier has: a first main amplifier connected to an input terminal side of the Doherty amplifier; a second main amplifier connected to an output terminal side of the Doherty amplifier; and a first inter-stage matching circuit that connects the first main amplifier to the second main amplifier, and
the peak amplifier has: a first peak amplifier connected to the input terminal side of the Doherty amplifier; a second peak amplifier connected to the output terminal side of the Doherty amplifier; and a second inter-stage matching circuit that connects the first peak amplifier to the second peak amplifier.

### (Appendix 5)

The Doherty amplifier according to appendix 4, wherein
the resin substrate has an annular portion that forms the cavity, and
the partition wall part extends between the second main amplifier and the second peak amplifier from the annular portion.

### (Appendix 6)

The Doherty amplifier according to appendix 4 or 5, wherein the inductor separates a wire, which connects the first inter-stage matching circuit to the second main amplifier, from a wire which connects the second inter-stage matching circuit to the second peak amplifier.

### (Appendix 7)

The Doherty amplifier according to any one of appendixes 4 to 6, wherein the inductor separates a wire, which is connected to an output side of the second main amplifier, from a wire which is connected to an output side of the second peak amplifier.

### (Appendix 8)

The Doherty amplifier according to any one of appendixes 4 to 7, wherein the inductor is mounted on a top surface of the partition wall part locally at a position adjacent to a wire connected to the second main amplifier or the second peak amplifier.

### (Appendix 9)

The Doherty amplifier according to any one of appendixes 1 to 8, wherein the main amplifier is constituted by a plurality of chips, and
a top surface of the inductor is placed at a higher position than a wire connecting the plurality of chips.

### (Appendix 10)

The Doherty amplifier according to any one of appendixes 1 to 9, wherein
the cavity is divided into a first cavity and a second cavity by the partition wall part,
the main amplifier is mounted in the first cavity, and
the peak amplifier is mounted in the second cavity.

### (Appendix 11)

The Doherty amplifier according to any one of appendixes 4 to 8, wherein the first main amplifier and the first peak amplifier are mounted on one chip.

### (Appendix 12)

The Doherty amplifier according to appendix 1, comprising:
a parallel circuit in which a first inductor and a first capacitor are connected in parallel, and
a series circuit in which a second inductor and a second capacitor are connected in series, wherein
one end of the parallel circuit is electrically connected to the heat sink,
another end of the parallel circuit is electrically connected to one end of the series circuit,
another end of the series circuit is electrically connected to the heat sink,
the inductor includes the first inductor or the second inductor, and
a resonant frequency of the parallel circuit is equal to an operating center frequency of the Doherty amplifier.

### (Appendix 13)

The Doherty amplifier according to appendix 12, wherein
the main amplifier has: a first main amplifier connected to an input terminal side of the Doherty amplifier; a second main amplifier connected to an output terminal side of the Doherty amplifier; and a first inter-stage matching circuit that connects the first main amplifier to the second main amplifier, and
the peak amplifier has: a first peak amplifier connected to the input terminal side of the Doherty amplifier; a second peak amplifier connected to the output terminal side of the Doherty amplifier; and a second inter-stage matching circuit that connects the first peak amplifier to the second peak amplifier.

### (Appendix 14)

The Doherty amplifier according to appendix 13, wherein the inductor separates a wire, which connects the first inter-stage matching circuit to the second main amplifier, from a wire which connects the second inter-stage matching circuit to the second peak amplifier.

### (Appendix 15)

The Doherty amplifier according to any one of appendixs 12 to 14, wherein
the first inductor and the second inductor are chip inductors, and
the first capacitor and the second capacitor are chip capacitors.

A Doherty amplifier according to the present disclosure can improve the isolation between the main amplifier and the peak amplifier at low cost by a partition wall part and an inductor.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2023-220795, filed on Dec. 27, 2023 including specification, claims, drawings and summary, on which the Convention priority of the present application is based, are incorporated herein by reference in its entirety.

1. A Doherty amplifier comprising:
a heat sink;
a resin substrate mounted on the heat sink, and having a cavity formed to expose the heat sink, the resin substrate being formed by stacking a plurality of resin layers and a plurality of metal layers;
a main amplifier mounted in the cavity;
a peak amplifier mounted in the cavity; and
an inductor, wherein
the resin substrate has a partition wall part that separates at least a portion of the main amplifier from at least a portion of the peak amplifier,
the plurality of metal layers of the partition wall part are electrically connected to the heat sink, and
the inductor is mounted on the partition wall part, and electrically connected to the plurality of metal layers.

2. The Doherty amplifier according to claim 1, wherein the inductor is a chip inductor.

3. The Doherty amplifier according to claim 1, wherein the plurality of metal layers and the heat sink are electrically connected through a VIA hole formed in the resin substrate.

4. The Doherty amplifier according to claim 1, wherein
the main amplifier has: a first main amplifier connected to an input terminal side of the Doherty amplifier; a second main amplifier connected to an output terminal side of the Doherty amplifier; and a first inter-stage matching circuit that connects the first main amplifier to the second main amplifier, and
the peak amplifier has: a first peak amplifier connected to the input terminal side of the Doherty amplifier; a second peak amplifier connected to the output terminal side of the Doherty amplifier; and a second inter-stage matching circuit that connects the first peak amplifier to the second peak amplifier.

5. The Doherty amplifier according to claim 4, wherein
the resin substrate has an annular portion that forms the cavity, and
the partition wall part extends between the second main amplifier and the second peak amplifier from the annular portion.

6. The Doherty amplifier according to claim 4, wherein the inductor separates a wire, which connects the first inter-stage matching circuit to the second main amplifier, from a wire which connects the second inter-stage matching circuit to the second peak amplifier.

7. The Doherty amplifier according to claim 4, wherein the inductor separates a wire, which is connected to an output side of the second main amplifier, from a wire which is connected to an output side of the second peak amplifier.

8. The Doherty amplifier according to claim 4, wherein the inductor is mounted on a top surface of the partition wall part locally at a position adjacent to a wire connected to the second main amplifier or the second peak amplifier.

9. The Doherty amplifier according to claim 1, wherein the main amplifier is constituted by a plurality of chips, and
a top surface of the inductor is placed at a higher position than a wire connecting the plurality of chips.

10. The Doherty amplifier according to claim 1, wherein
the cavity is divided into a first cavity and a second cavity by the partition wall part,
the main amplifier is mounted in the first cavity, and
the peak amplifier is mounted in the second cavity.

11. The Doherty amplifier according to claim 4, wherein the first main amplifier and the first peak amplifier are mounted on one chip.

12. The Doherty amplifier according to claim 1, comprising:
a parallel circuit in which a first inductor and a first capacitor are connected in parallel, and
a series circuit in which a second inductor and a second capacitor are connected in series, wherein
one end of the parallel circuit is electrically connected to the heat sink,
another end of the parallel circuit is electrically connected to one end of the series circuit,
another end of the series circuit is electrically connected to the heat sink,
the inductor includes the first inductor or the second inductor, and
a resonant frequency of the parallel circuit is equal to an operating center frequency of the Doherty amplifier.

13. The Doherty amplifier according to claim 12, wherein
the main amplifier has: a first main amplifier connected to an input terminal side of the Doherty amplifier; a second main amplifier connected to an output terminal side of the Doherty amplifier; and a first inter-stage matching circuit that connects the first main amplifier to the second main amplifier, and
the peak amplifier has: a first peak amplifier connected to the input terminal side of the Doherty amplifier; a second peak amplifier connected to the output terminal side of the Doherty amplifier; and a second inter-stage matching circuit that connects the first peak amplifier to the second peak amplifier.

14. The Doherty amplifier according to claim 13, wherein the inductor separates a wire, which connects the first inter-stage matching circuit to the second main amplifier, from a wire which connects the second inter-stage matching circuit to the second peak amplifier.

15. The Doherty amplifier according to claim 12, wherein
the first inductor and the second inductor are chip inductors, and
the first capacitor and the second capacitor are chip capacitors.
